(19) United States
(12) Patent Application Publication
(10) Pub. No.: US 2019/0081089 A1
(43) Pub. Date: Mar. 14, 2019

(54) DISPLAY DEVICE, MANUFACTURING METHOD OF DISPLAY DEVICE, AND ELECTRODE FORMING METHOD

(71) Applicant: SAMSUNG DISPLAY CO., LTD., Yongin-si (KR)

(72) Inventors: Hyun Min CHO, Yongin-si (KR); Shin Il CHOI, Yongin-si (KR); Sang Gab KIM, Yongin-si (KR); Su Bin BAE, Yongin-si (KR); Yu Gwang JEONG, Yongin-si (KR)

(21) Appl. No.: 16/124,387

(22) Filed: Sep. 7, 2018

(30) Foreign Application Priority Data
Sep. 8, 2017 (KR) 10-2017-0115077

(51) Int. Cl. H01L 27/12; H01L 29/49; H01L 21/3213; H01L 29/786

(52) U.S. Cl. CPC H01L 27/1251; H01L 27/1225; H01L 27/1229; H01L 27/1255; H01L 29/7869; H01L 29/4958; H01L 27/1262; H01L 21/32135; H01L 29/78675; H01L 27/1237

(57) ABSTRACT

A display device includes: a substrate; first and second transistors provided on the substrate to be spaced apart from each other; and a display unit electrically connected to the first transistor, wherein the first transistor includes a first semiconductor layer including crystalline silicon, a first gate electrode, a first source electrode, and a first drain electrode, wherein the second transistor includes a second semiconductor layer including an oxide semiconductor, a second gate electrode, a second source electrode, and a second drain electrode, and wherein the second gate electrode includes a first layer that is provided on an insulating layer and includes molybdenum, a second layer that is provided on the first layer and includes titanium, and a third layer that is provided on the second layer and includes molybdenum.

### CROSS-REFERENCE TO RELATED APPLICATION

Korean Patent Application No. 10-2017-0115077, filed on Sep. 8, 2017, in the Korean Intellectual Property Office, and entitled: “Display Device, Manufacturing Method of Display Device, and Electrode Forming Method,” is incorporated by reference herein in its entirety.

### BACKGROUND

### 1. Field

Embodiments relate to a display device, a manufacturing method of a display device, and an electrode forming method.

### 2. Description of the Related Art

Display devices have come into the spotlight because of their light weight and thin thickness. Among the display devices, an organic light emitting display device is a self-luminescent display device that displays an image using organic light emitting diodes that emit light, and does not require any separate light source. Also, the organic light emitting display device has low power consumption, high luminance, and high speed of response, and thus has drawn attention as a next-generation display device.

The organic light emitting display device includes a plurality of pixels, each of which includes an organic light emitting diode, a plurality of transistors for driving the organic light emitting diode, and at least one capacitor.

### SUMMARY

Embodiments are directed to a display device including: a substrate; first and second transistors provided on the substrate to be spaced apart from each other; and a display unit electrically connected to the first transistor, wherein the first transistor includes a first semiconductor layer including crystalline silicon, a first gate electrode, a first source electrode, and a first drain electrode, wherein the second transistor includes a second semiconductor layer including an oxide semiconductor, a second gate electrode, a second source electrode, and a second drain electrode, and wherein the second gate electrode includes a first layer that is provided on an insulating layer and includes molybdenum, a second layer that is provided on the first layer and includes titanium, and a third layer that is provided on the second layer and includes molybdenum.

The display device may further include: a first insulating layer provided between the first gate electrode and the first semiconductor layer; a second insulating layer provided over the first gate electrode; and a third insulating layer provided between the second gate electrode and the second semiconductor layer. The insulating layer may be one of the second insulating layer and the third insulating layer.

The second gate electrode may be provided on the third insulating layer.

The display device may further include: a capacitor electrode provided on the second insulating layer; and a fourth insulating layer covering the capacitor electrode, the fourth insulating layer being provided between the second insulating layer and the second semiconductor layer.

At least one selected from the first gate electrode and the capacitor electrode may include the first layer, the second layer on the first layer, and the third layer on the second layer.

The second gate electrode may be provided on the second insulating layer, and the second semiconductor layer may be provided on the third insulating layer.

The display device may further include a capacitor electrode provided on the second insulating layer, the capacitor electrode overlapping with the first gate electrode.

At least one selected from the first gate electrode and the capacitor electrode may include the first layer, the second layer on the first layer, and the third layer on the second layer.

The thickness of the third layer may be thicker than the first layer.

The display unit may include: a first electrode electrically connected to the first drain electrode; a second electrode provided on the first electrode; and an emitting layer provided between the first electrode and the second electrode.

Embodiments are also directed to a method of manufacturing a display device, the method including: providing a first semiconductor layer including crystalline silicon on a substrate; providing a first insulating layer over the first semiconductor layer; providing a first gate electrode on the first insulating layer; providing a second insulating layer over the first gate electrode; providing, on the second insulating layer, a second semiconductor layer spaced apart from the first gate electrode, the second semiconductor layer including an oxide semiconductor; providing a third insulating layer over the second semiconductor layer; and providing a second gate electrode on the third insulating layer, wherein the second gate electrode includes a first layer that is provided on the third insulating layer and includes molybdenum, a second layer that is provided on the first layer and includes titanium, and a third layer that is provided on the second layer and includes molybdenum, and wherein the providing of the second gate electrode includes: a first etching process of etching the second layer and the third layer; and a second etching process of etching the first layer.

The method may further include: between the providing of the second insulating layer and the providing of the second semiconductor layer, forming a capacitor electrode overlapping the first gate electrode on the second insulating layer; and providing a fourth insulating layer provided over the capacitor electrode.

The etching speed of an etching gas used in the first etching process with respect to the third layer may be 0.9 times to 1.1 times of that of the etching gas used in the first etching process with respect to the second layer.

The etching gas used in the first etching process may include sulfur hexafluoride (SF₆) and oxygen (O₂), and an etching gas used in the second etching process may include chlorine (Cl₂) and oxygen (O₂).

Embodiments are also directed to a method of manufacturing a display device, the method including: providing a first semiconductor layer including crystalline silicon on a substrate; providing a first insulating layer over the first semiconductor layer; providing a first gate electrode on the first insulating layer; providing a second insulating layer over the first gate electrode; providing a second gate electrode spaced apart from the first gate electrode on the second insulating layer; providing a third insulating layer over the second gate electrode; and providing a second semiconductor layer including an oxide semiconductor on the third insulating layer, wherein the second gate electrode includes a first layer that is provided on the third insulating layer and includes molybdenum, a second layer that is provided on the first layer and includes titanium, and a third layer that is provided on the second layer and includes molybdenum, and wherein the providing of the second gate electrode includes: a first etching process of etching, the second layer and the third layer; and a second etching process of etching the first layer.

The method may further include providing a capacitor electrode that is provided on the second insulating layer, overlaps with the first gate electrode, and is simultaneously formed with the second gate electrode.

The etching speed of an etching gas used in the first etching process with respect to the third layer may be 0.9 times to 1.1 times of that of the etching gas used in the first etching process with respect to the second layer.

The etching gas used in the first etching process may include sulfur hexafluoride (SF₆) and oxygen (O₂), and an etching gas used in the second etching process may include chlorine (Cl₂) and oxygen (O₂).

Embodiments are also directed to a method of forming an electrode, the method including: sequentially forming a first layer that includes molybdenum, a second layer that is provided on the first layer and includes titanium, and a third layer that is provided on the second layer and includes molybdenum; a first etching process of etching the third layer and the second layer in a lump; and a second etching process of etching the first layer, wherein the etching speed of an etching gas used in the first etching process with respect to the third layer is 0.9 times to 1.1 times of that of the etching gas used in the first etching process with respect to the second layer.

The etching gas used in the first etching process may include sulfur hexafluoride (SF₆) and oxygen (O₂), and an etching gas used in the second etching process may include chlorine (Cl₂) and oxygen (O₂).

### BRIEF DESCRIPTION OF THE DRAWINGS

Features will become apparent to those of skill in the art by describing in detail example embodiments with reference to the attached drawings in which:

FIG. 1 illustrates a sectional view of a display device according to an embodiment.

FIG. 2 illustrates an enlarged sectional view illustrating region A1 of FIG. 1.

FIG. 3 illustrates a sectional view of a display device according to another embodiment.

FIGS. 4A to 4S illustrate process sectional views illustrating a manufacturing method of the display device shown in FIG. 1.

FIGS. 5A to 5G illustrate process sectional views illustrating a manufacturing method of the display device shown in FIG. 3.

FIGS. 6A to 6F illustrate process sectional views illustrating an electrode forming method according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

The present disclosure may apply various changes and different shape, therefore only illustrate in details with particular examples. However, the examples do not limit to certain shapes but apply to all the change and equivalent material and replacement.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

Hereinafter, example embodiments will be described in detail with reference to the accompanying drawings.

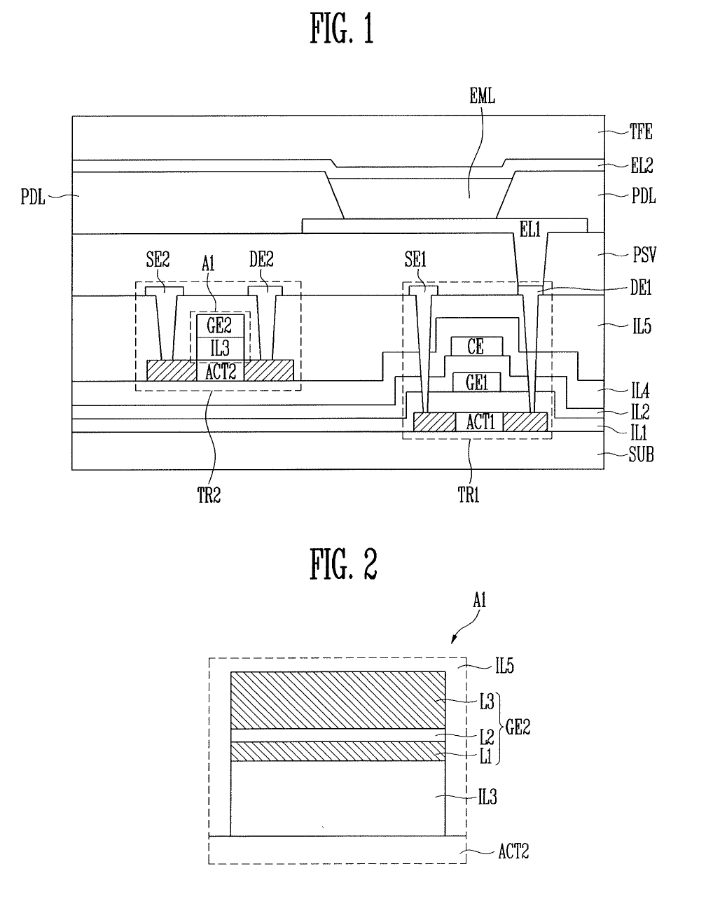

FIG. 1 is a sectional view of a display device according to an embodiment. FIG. 2 is an enlarged sectional view illustrating region A1 of FIG. 1.

Referring to FIG. 1, the display device includes a substrate SUB, a first transistor TR1 and a second transistor TR2, which are provided on the substrate SUB to be spaced apart from each other, and a display unit electrically connected to the first transistor TR1.

Hereinafter, each component included in the display device will be described in more detail.

The substrate SUB on which the first transistor TR1 and the second transistor TR2 are provided may include a transparent insulating material to enable light to be transmitted therethrough. The substrate SUB may be a rigid substrate. For example, the substrate SUB may be any one of a glass substrate, a quartz substrate, a glass ceramic substrate, and a crystalline glass substrate.

In addition, the substrate SUB may be a flexible substrate. Here, the substrate SUB may be one of a film substrate and a plastic substrate, including a polymer organic material. For example, the substrate SUB may include at least one selected from the group of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material constituting the substrate SUB may be variously changed, and include a fiber reinforced plastic (FRP), etc.

The material applied to the substrate SUB may have resistance (or heat resistance) against high processing temperature in a manufacturing process of the display device.

The first transistor TR1 and the second transistor TR2 are provided on the substrate SUB.

A buffer layer may be further provided between the substrate SUB and the first transistor TR1. The buffer layer may have a single- or multi-layered structure. Also, the buffer layer may include at least one of an inorganic insulating material and an organic insulating material. For example, when the buffer layer has a single-layered structure of an inorganic insulating material, the buffer layer may include one of a silicon oxide layer, a silicon nitride layer, and a silicon oxynitride layer. When the buffer layer has a multi-layered structure of an inorganic insulating material, the buffer layer may have a multi-layered structure in which a silicon oxide layer and a silicon nitride layer are alternately stacked. When the buffer layer has a single-layered structure of an organic insulating material, the buffer layer may include at least one of acryl, polyimide, polyamide, and benzocyclobutene. When the buffer layer has a multi-layered structure of an organic insulating material, the buffer layer may have a structure in which the plurality of organic insulating layers including at least one of acryl, polyimide, polyamide, and benzocyclobutene are stacked. Also, the buffer layer may have a structure in which an inorganic insulating layer and an organic insulating layer are alternately stacked.

The buffer layer may prevent impurities from being diffused into the transistor, and prevents moisture and oxygen from penetrating into the transistor. Also, the buffer layer may planarize a surface of the substrate SUB. In some cases, the buffer layer may be omitted.

The first transistor TR1 is provided on the substrate SUB, and includes a first semiconductor layer ACT1 including crystalline silicon, a first gate electrode GE1 provided on the first semiconductor layer ACT1, a first insulating layer IL1 provided between the first gate electrode GE1 and the first semiconductor layer ACT1, a second insulating layer IL2 provided over the first gate electrode GE1, and a first source electrode SE1 and a first drain electrode DE1, which are provided to be spaced apart from each other and are connected to the first semiconductor layer ACT1.

The first semiconductor layer ACT1 provided on the substrate SUB includes crystalline silicon. The crystalline silicon may be single crystalline silicon and/or multi-crystalline silicon. As compared with a semiconductor layer including amorphous silicon, the first semiconductor layer ACT1 including the crystalline silicon has a high electron mobility. In the case of amorphous silicon, electron mobility may be relatively decreased due to irregular arrangement of silicon atoms.

In addition, the first semiconductor layer ACT1 may include a source region and a drain region, which are respectively in contact with the first source electrode SE1 and the first drain electrode DEL The source region and the drain region may be doped regions. A region between the source region and the drain region may be a channel region.

The first semiconductor layer ACT1 including the crystalline silicon may be formed by crystallizing the amorphous silicon. The process of crystallizing the amorphous silicon may be performed at a high or low temperature. When the amorphous silicon is crystallized at a high temperature, the substrate SUB may be made of a heat resistance material which can endure the high-temperature process.

The method of crystallizing the amorphous silicon at a low temperature may include a solid phase crystallization (SPC) method, a metal induced crystallization (MIC) method, a metal induced lateral crystallization (MILC) method, an excimer laser crystallization (ELC) method, or the like.

The SPC method is a method of annealing the amorphous silicon at a relatively high temperature for a long time. The SPC method may be generally performed by annealing the amorphous silicon at about 600° C. to about 700° C. for about 1 hour to 24 hours.

According to the MIC method, the crystallization temperature of the amorphous silicon may be lowered by allowing the amorphous silicon to be in contact with a specific metal. Examples of the metal used herein may be nickel (Ni), palladium (Pd). titanium (Ti), aluminum (Al), gold (Au), silver (Ag), copper (Cu), cobalt (Co), iron (Fe), manganese (Mn), or the like. These metals form a eutectic phase or a silicide phase by reacting with the amorphous silicon, so that the crystallization of the amorphous silicon is accelerated.

The ELC method is a method of crystallizing the amorphous silicon by irradiating excimer laser onto the amorphous silicon. The amorphous silicon has a very high absorption coefficient in an ultraviolet region to which the wavelength of the excimer laser belongs. Thus, the amorphous silicon absorbs energy of the excimer laser without loss, and accordingly may be easily melted. The melted amorphous silicon may be phase-changed into the crystalline silicon in a process of solidifying the melted amorphous silicon.

The ELC method has a short process time, and may be locally performed. Hence, the ELC method does not damage the substrate SUB. In addition, the crystalline silicon formed by the ELC method exhibits a thermodynamically stable crystalline grain structure.

The first gate electrode GE1 may be provided on the first semiconductor layer ACT1. The first gate electrode GE1 may apply an electric field onto the first semiconductor layer ACT1. A current flows or does not flow in the channel region of the first semiconductor layer ACT1 according to the electric field applied onto the first semiconductor layer ACT1.

The first gate electrode GE1 may include a conductive material. For example, the first gate electrode GE1 may include at least one of aluminum (Al), silver (Ag), tungsten (W), copper (Cu), nickel (Ni), chromium (Cr), molybdenum (Mo), titanium (Ti), platinum (Pt), tantalum (Ta), neodymium (Nd), scandium (Sc), and an alloy thereof.

The first insulating layer IL1 may be provided between the first gate electrode GE1 and the first semiconductor layer ACT1. The first insulating layer IL1 insulates the first gate electrode GE1 and the first semiconductor layer ACT1 from each other.

The first insulating layer IL1 may have a single-layered or multi-layered structure. Also, the first insulating layer IL1 may include at least one of an inorganic insulating material and an organic insulating material. For example, when the first insulating layer IL1 has a single-layered structure of an inorganic insulating material, the first insulating layer IL1 may include one of a silicon oxide layer, a silicon nitride layer, and a silicon oxynitride layer. When the first insulating layer IL1 has a multi-layered structure of an inorganic insulating material, the first insulating layer IL1 may have a structure in which a silicon oxide layer and a silicon nitride layer are alternately stacked. When the first insulating layer IL1 has a single-layered structure of an organic insulating material, the first insulating layer IL1 may include at least one of acryl, polyimide, polyamide, and benzocyclobutene. When the first insulating layer IL1 has a multi-layered structure of an organic insulating material, the first insulating layer IL1 may have a structure in which the above-described materials are stacked in several layers. Also, the first insulating layer IL1 may also have a structure in which an inorganic insulating layer and an organic insulating layer are alternately stacked.

In addition, the capacitance of the first insulating layer IL1 may be minimized so as to minimize a parasitic capacitance that may be generated between the first gate electrode GE1 and the first source electrode SE1 and/or the first drain electrode DE1.

The second insulating layer IL2 is provided over the first gate electrode GE1. Like the first insulating layer IL1, the second insulating layer IL2 may include at least one of an inorganic insulating material and an organic insulating material. Descriptions of inorganic and organic insulating materials that may be included in the second insulating layer IL2 are the same as those of the first insulating layer IL1.

According to an embodiment, a capacitor electrode CE may be provided on the second insulating layer IL2. The capacitor electrode CE is provided to be spaced apart from the first gate electrode GE1 with the second insulating layer IL2 interposed therebetween. The capacitor electrode CE overlaps with the first gate electrode GE1 and forms a capacitance. The size of the capacitor electrode CE and the thickness of the second insulating layer IL2 are adjusted, so that the capacitance may be controlled.

The capacitor electrode CE may include a conductive material. For example, the capacitor electrode CE may include at least one of aluminum (Al), silver (Ag), tungsten (W), copper (Cu), nickel (Ni), chromium (Cr), molybdenum (Mo), titanium (Ti), platinum (Pt), tantalum (Ta), neodymium (Nd), scandium (Sc), and an alloy thereof.

A fourth insulating layer IL4 may be provided over the capacitor electrode CE. Like the first insulating layer IL 1, the fourth insulating layer IL4 may include at least one of an inorganic insulating material and an organic insulating layer. Descriptions of inorganic and organic insulating materials that may be included in the fourth insulating layer IL4 are the same as those of the first insulating layer IL1.

A fifth insulating layer IL5 is provided on the fourth insulating layer IL4. The fifth insulating layer IL5 may include at least one of an inorganic insulating layer made of an inorganic material and an organic insulating layer made of an organic material.

The first source electrode SE1 and the first drain electrode DE1 may be provided on the fifth insulating layer IL5.

The first source electrode SE I and the first drain electrode DE1 may be in contact with the source region and the drain region of the first semiconductor layer ACT1 through contact holes passing through the fifth insulating layer IL5, the fourth insulating layer IL4, the second insulating layer IL2, and the first insulating layer IL1, respectively. The source region and the drain region may be regions in which doping is performed on the first semiconductor layer ACT1.

The second transistor TR2 may be provided on the second insulating layer IL2.

The second transistor TR2 includes a second semiconductor layer ACT2 that is provided on the second insulating layer IL2 and includes an oxide semiconductor, a second gate electrode GE2 provided on the top or bottom of the second semiconductor layer ACT2, a second source electrode SE2 and a second drain electrode DE2, which are provided to be spaced apart from each other and are connected to the second semiconductor layer ACT2, and a third insulating layer IL3 provided between the second gate electrode GE2 and the second semiconductor layer ACT2.

The second semiconductor layer ACT2 is provided on the second insulating layer IL2.

The second semiconductor layer ACT2 may be in contact with the second insulating layer IL2. However, in some embodiments, the third insulating layer IL3 or the fourth insulating layer IL4 may be further provided between the second semiconductor layer ACT2 and the second insulating layer IL2.

The second semiconductor layer ACT2 may include an oxide semiconductor. The oxide semiconductor included in the second semiconductor layer ACT2 may include at least one of one-component metal oxide such as indium (In) oxide, tin (Sn) oxide, or zinc (Zn) oxide, two-component metal oxide such as In-Zn-based oxide, Sn-Zn-based oxide, Al-Zn-based oxide. Zn-Mg-based oxide, Sn-Mg-based oxide, In-Mg-based oxide, or In-Ga-based oxide, three-component metal oxide such as In-Ga-Zn-based oxide, In-Al-Zn-based oxide, In-Sn-Zn-based oxide, Sn-Ga-Zn-based oxide, Al-Ga-Zn-based oxide, Sn-Al-Zn-based oxide, In-Hf-Zn-based oxide, In-La-Zn-based oxide, In-Ce-Zn-based oxide, In-Pr-Zn-based oxide, In-Nd-Zn-based oxide, In-Sm-Zn-based oxide, In-Eu-Zn-based oxide, In-Gd-Zn-based oxide, In-Tb-Zn-based oxide, In-Dy-Zn-based oxide, In-Ho-Zn-based oxide, In-Er-Zn-based oxide, In-Tm-Zn-based oxide, In-Yb-Zn-based oxide, or In-Lu-Zn-based oxide, and four-component metal oxide such as In-Sn-Ga-Zn-based oxide, In-Hf-Ga-Zn-based oxide, In-Al-Ga-Zn-based oxide, In-Sn-Al-Zn-based oxide, In-Sn-Hf-Zn-based oxide, or In-Hf-Al-Zn-based oxide.

For example, the second semiconductor layer ACT2 may include indium-gallium-zinc oxide (IGZO) in the In-Ga-Zn-based oxide.

The oxide semiconductor included in the second semiconductor layer ACT2 is a compound semiconductor formed by ionic bonding of a positive ion of a metal and a negative ion of oxygen. Accordingly, the main component of conduction band minimum (CBM) of the oxide semiconductor is an s orbital of the metal constituting the oxide semiconductor, and the main component of valence band maximum (VBM) is a p orbital.

Major carriers of the oxide semiconductor are electrons, and the oxide semiconductor is of an n-type. Electrical characteristics of the oxide semiconductor relay on the vacancy of oxygen and the concentration of hydrogen doped into the oxide semiconductor during a process. In particular, the hydrogen has influence on the carrier concentration of the oxide semiconductor.

The second semiconductor layer ACT2 may include a source region and a drain region, which are respectively in contact with the second source electrode SE2 and the second drain electrode DE2. A region between the source region and the drain region may be a channel region.

An etch stop layer may be further provided on the second semiconductor layer ACT2. The etch stop layer may be provided on the second semiconductor layer ACT2, to prevent the second semiconductor layer ACT2 from being degraded in the manufacturing process of the display device.

The display device according to the present example embodiment includes the first transistor TR1 and the second transistor TR2, which are spaced apart from each other. The first transistor TR1 includes the first semiconductor layer ACT1 including crystalline silicon, and the second transistor TR2 includes the second semiconductor layer ACT2 including an oxide semiconductor.

According to the present example embodiment, the first and second transistors TR1 and TR2 including the first and second semiconductor layers ACT1 and ACT2 formed of different materials respectively are provided on the substrate SUB to be spaced apart from each other, so that it is possible to simultaneously obtain advantages of the transistor including the oxide semiconductor and advantages of the transistor including crystalline silicon.

For example, the transistor including the crystalline silicon, which has a very high electron mobility speed in a semiconductor layer but has high processing cost, may be provided in a region required to rapidly transfer a signal. In addition, the transistor including the oxide semiconductor, which has an electron mobility speed relatively lower than that of the transistor including the crystalline silicon but has low processing cost and prevents leakage current, may be provided in a region in which leakage current may be generated.

For example, according to an embodiment, the first transistor TR1 that includes the first semiconductor layer ACT1 including the crystalline silicon may serve as a driving transistor. In addition, the second transistor TR2 that includes the second semiconductor layer ACT2 including the oxide semiconductor may serve as a switching transistor. However, the above-described functions of the first transistor TR1 and the second transistor TR2 are merely illustrative.

In addition, although only the first transistor TR1 and the second transistor TR2 of the display device are illustrated in FIG. 1, a larger number of transistors and capacitors may be included in the display device, if necessary. For example, the display device may include seven transistors and one capacitor. However, even when the display device includes two or more transistors, at least one transistor includes a semiconductor layer including an oxides semiconductor, and at least one transistor includes a semiconductor layer including crystalline silicon.

The second gate electrode GE2 is provided on the top or bottom of the second semiconductor layer ACT2.

As can be seen in FIG. 2, the second gate electrode GE2 includes at least three layers L1, L2, and L3. At this time, a first layer L1 includes molybdenum (Mo), a second layer L2 includes titanium (Ti), and a third layer L3 includes molybdenum (Mo). Therefore, the second gate electrode GE2 according to the present example embodiment may have a form in which molybdenum/titanium/molybdenum are sequentially stacked. However, in addition to the above-described first to third layers L1 to L3, another layer may be further included in the second gate electrode GE2. For example, a layer including another metal may be provided between the first layer L1 and the second layer L2 or between the second layer L2 and the third layer L3.

The first layer L1 and the third layer L3 include molybdenum as described above. Here, that the first layer L1 and the third layer L3 include molybdenum may include not only a case where the first layer L1 and the third layer L3 are purely made of molybdenum but also a case where the first layer L1 and the third layer L3 are made of an alloy including molybdenum. However, the content of molybdenum in the alloy including molybdenum is higher than those of other metals.

Similarly, that the second layer L2 includes titanium may include not only a case where the second layer L2 is purely made of titanium but also a case where the second layer L2 is made of an alloy including titanium. However, the content of titanium in the alloy including titanium is higher than those of other metals.

According to an embodiment, the first layer L1 may meet the third insulating layer IL3 provided between the second semiconductor layer ACT2 and the second gate electrode GE2. The first layer L1 including molybdenum may prevent the third insulating layer IL3 and the second layer L2 from reacting with each other. When the third insulating layer IL3 includes oxide or oxynitride, the titanium of the second layer L2 may be changed into titanium oxide (TiOₓ) by reacting with the third insulating layer IL3. In this case, the first layer L1 prevents the occurrence of such a reaction.

When the titanium oxide (TiOₓ) is included in the second layer L2, the etch uniformity of the second layer L2 may be degraded. This is because the reactivity of the titanium with respect to a fluid for etching is different from that of the titanium oxide (TiOₓ) for the fluid for etching. In addition, the titanium oxide exists in a residual form in the third insulating layer IL3, and therefore, a failure may be caused.

The second layer L2 including the titanium prevents hydrogen from being diffused into the second semiconductor layer ACT2 including the oxide semiconductor. Since the hydrogen has influence on the carrier concentration of the second semiconductor layer ACT2 including the oxide semiconductor, it is preferable to prevent the hydrogen from being unnecessarily injected into the second semiconductor layer ACT2 during a process.

The first to third layers L1 to L3 may have thicknesses different from one another. For example, the thickness of the third layer L3 is thickest, and the first layer L1 may be thicker than the second layer L2.

The third insulating layer IL3 is provided between the second gate electrode GE2 and the second semiconductor layer ACT2. The third insulating layer IL3 may have a single- or multi-layered structure. Also, the third insulating layer IL3 may include at least one of an inorganic insulating material and an organic insulating material. For example, when the third insulating layer IL3 has a single-layered structure of an inorganic insulating material, the third insulating layer IL3 may include one of a silicon oxide layer, a silicon nitride layer, and a silicon oxynitride layer. When the third insulating layer IL3 has a multi-layered structure of an inorganic insulating material, the third insulating layer IL3 may have a structure in which a silicon oxide layer and a silicon nitride layer are alternately stacked.

When the third insulating layer IL3 includes an inorganic insulating material, a silicon oxide layer may be provided at a surface of the third insulating layer IL3 that meets the second semiconductor layer ACT2. In the case of a silicon nitride layer, oxygen may penetrate into the second semiconductor layer ACT2 in a process of forming the silicon nitride layer, using plasma-enhanced chemical vapor deposition (PECVD). Electrical characteristics of the second semiconductor layer ACT2 may be changed by the penetrating oxygen, and hence the silicon oxide layer may be provided at the surface of the third insulating layer IL3 that meets the second semiconductor layer ACT2.

In addition, the third insulating layer IL3 may include an organic layer. When the third insulating layer IL3 has a single-layered structure of an organic insulating material, the third insulating layer IL3 may include at least one of acryl, polyimide, polyamide, and benzocyclobutene. When the third insulating layer IL3 has a multi-layered structure of an organic insulating material, the third insulating layer IL3 may have a structure in which the above-described materials are stacked in several layers.

In addition, the third insulating layer IL3 may be provided in a shape capable of minimizing parasitic capacitance that may be generated between the second gate electrode GE2 and the second source electrode SE2 and/or the second drain electrode DE2. To this end, the third insulating layer IL3 may be provided in an island shape having an area similar to that of the second gate electrode GE2. However, the shape of the third insulating layer IL3 is not limited thereto, and the third insulating layer IL3 may be entirely formed on the substrate SUB, like the first insulating layer IL1.

The second source electrode SE2 and the second drain electrode DE2 may be provided on the fifth insulating layer IL5. The second source electrode SE2 and the second drain electrode DE2 may be in contact with a source region and a drain region of the second semiconductor layer ACT2 through contact holes passing through the fifth insulating layer IL5, respectively. A region between the source region and the drain region of the second semiconductor layer ACT2 including the oxide semiconductor may be a channel region.

A protective layer PSV is provided over the first source electrode SE1, the first drain electrode DE1 the second source electrode SE2, and the second drain electrode DE2. The protective layer PSV covers the first transistor TR1 and the second transistor TR2. The protective layer PSV may include at least one of an inorganic insulating layer made of an inorganic material and an organic insulating layer made of an organic material.

A first electrode EL1, an emitting layer EML, and a second electrode EL2 are provided on the protective layer PSV. The first electrode EL1, the emitting layer EML, and the second electrode EL2 may constitute a light emitting device (i.e. display unit) that performs a function of receiving a signal applied to the first transistor TR1 to emit light.

Any one of the first electrode EL1 and the second electrode EL2 may be an anode electrode, and the other of the first electrode EL1 and the second electrode EL2 may be a cathode electrode. For example, when the first electrode EL1 may be an anode electrode, and the second electrode EL2 may be a cathode electrode. When the light emitting device is a top emission type organic light emitting device, the first electrode EL1 may be a reflective electrode, and the second electrode EL2 may be a transmissive electrode. In the embodiment, a case where the light emitting device is a top emission type organic light emitting device, and the first electrode EL1 is an anode electrode will be described as an example.

The first electrode EL1 may be electrically connected to the first drain electrode DE1 of the first transistor TR1 through a contact hole passing through the protective layer PSV. The first electrode EL1 may include a reflective layer capable of reflecting light and a transparent conductive layer disposed on the top or bottom of the reflective layer. At least one of the transparent conductive layer and the reflective layer may be electrically connected to the first drain electrode DE1.

A pixel defining layer PDL having an opening that allows a portion of the first electrode EL1.e.g., a top surface of the first electrode EL1 to be exposed therethrough may be further provided on the protective layer PSV.

The pixel defining layer PDL may include an organic insulating material. For example, the pixel defining layer PDL may include at least one of polystyrene, polymethylmethacrylate (PMMA), polyacrylonitrile (PAN), polyamide (PA), polyimide (PI), polyarylether (PAE), heterocyclic polymer, parylene, epoxy, benzocyclobutene (BCB), siloxane based resin, and silane based resin.

The emitting layer EML may be provided on the exposed surface of the first electrode EL1.

The emitting layer EML may include a low-molecular or high-molecular material. In an embodiment, the low-molecular material may include copper phthalocyanine (CuPc), N,N′-Di(naphthalene-1-yl)-N,N′-diphenyl-benzidine (NPB), tris-8-hydroxyquinoline aluminum (Alq₃), or the like. The high-molecular material may include poly(3,4-ethylenedioxythiophene) (PEDOT)-, poly(phenylene-vinylene) (PPV)-, and/or poly(fluorine)-based materials.

The emitting layer EML not only may be provided as a single layer, but also may be provided as a multi-layer including various functional layers. When the emitting layer EML is provided as a multi-layer, the emitting layer EML may have a structure in which a hole injection layer, a hole transport layer, an emission layer, an electron transport layer, an electron injection layer, or the like are stacked in a single or complex structure. The form of the emitting layer EML is not limited thereto. The emitting layer ELM may have various structures in addition to the above-described structure. In addition, at least a portion of the emitting layer ELM may be integrally formed throughout a plurality of first electrodes EL1, or be individually provided to correspond to each of the plurality of first electrodes EL1. The color of light generated in the emitting layer EML may be one of red, green, blue, and white, but the present example embodiment is not limited thereto. For example, the color of light generated in a light generation layer of the emitting layer EML may be one of magenta, cyan, and yellow.

The second electrode EL2 may be provided on the emitting layer EML. The second electrode EL2 may be a semi-transmissive reflective layer. For example, the second electrode EL2 may be a thin metal layer having a thickness, through which light emitted through the emitting layer EML may be transmitted. The second electrode EL2 may allow a portion of the light emitted from the emitting layer EML to be transmitted therethrough, and allow the rest of the light emitted from the emitting layer EML to be reflected therefrom.

An encapsulation layer TFE may be provided on the light emitting device.

The encapsulation layer TFE may not only be formed in a single layer, but also be formed in a multi-layer. The encapsulation layer TFE may include a plurality of insulating layers that cover the light emitting device. For example, the encapsulation layer TFE may include a plurality of inorganic layers and a plurality of organic layers. For example, the encapsulation layer TFE may have a structure in which inorganic and organic layers are alternately stacked. In some cases, the encapsulation layer TFE may be an encapsulation substrate that is disposed on the light emitting device and is joined with the substrate SUB through a sealant.

An input sensing unit may be provided on the encapsulation layer TFE. The input sensing unit includes a plurality of sensing electrodes, and senses an input such as a touch of a user. The encapsulation layer TFE may serve as a base layer of the input sensing unit.

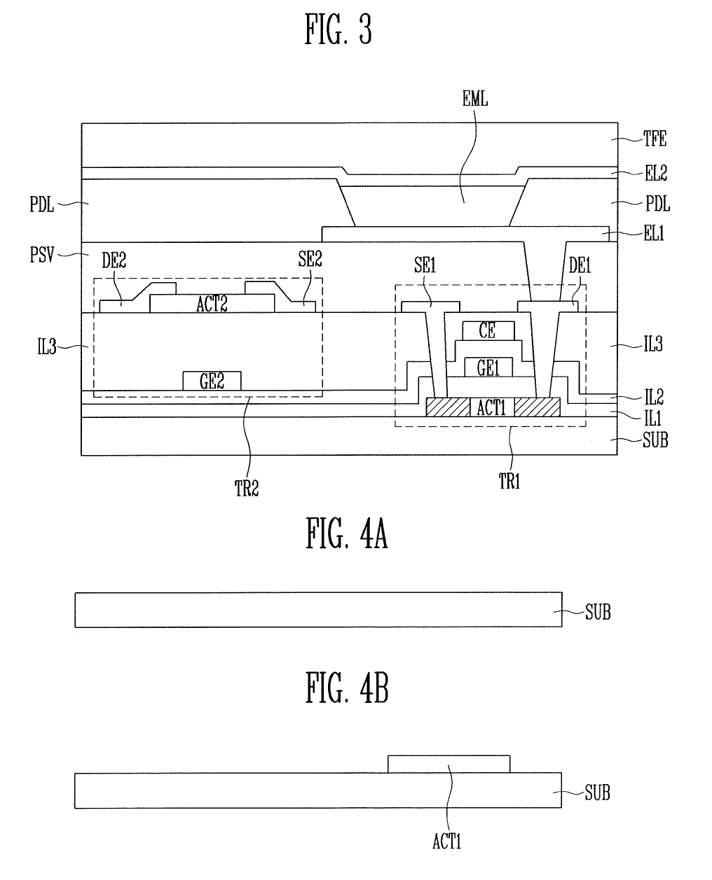

FIG. 3 is a sectional view of a display device according to another embodiment.

In the display device shown in FIG. 3, portions different from those of the display device shown in FIG. 1 will be mainly described.

Referring to FIG. 3, in a second transistor TR2, a second gate electrode GE2 is provided under a second semiconductor layer ACT2. Accordingly, the second gate electrode GE2 is provided on a second insulating layer IL2.

In the display device shown in FIG. 3, the second gate electrode GE2 also includes first to third layers that are sequentially stacked. The first layer and the third layer include molybdenum, and the second layer includes titanium. Therefore, the first layer of the second gate electrode GE2 is in contact with the second insulating layer IL2.

The first layer may prevent titanium oxide from being generated as the second insulating layer IL2 and the second layer including the titanium react with each other. In addition, the second layer may prevent hydrogen and/or oxygen from being diffused into the second semiconductor layer ACT2.

According to the embodiment shown in FIG. 3, a capacitor electrode CE may be provided on the second insulating layer IL2. Therefore, the capacitor electrode CE may be provided in the same layer as the second gate electrode GE2. When the capacitor electrode CE is provided in the same layer as the second gate electrode GE2, the capacitor electrode CE may include first to third layers that are sequentially stacked, like the second gate electrode GE2. In addition, the first layer and the third layer, which are included in the capacitor electrode CE, may include molybdenum, and the second layer included in the capacitor electrode CE may include titanium.

A third insulating layer IL3 is provided between the second gate electrode GE2 and the second semiconductor layer ACT2. The third insulating layer IL3 entirely covers the second gate electrode GE2. In addition, the third insulating layer IL3 also covers the capacitor electrode CE provided in the same layer as the second gate electrode GE2.

A first source electrode SE1 and a first drain electrode DE1 of a first transistor TR1 are connected to a source region and a drain region of a first semiconductor layer ACT1 through contact holes passing through the third insulating layer IL3, the second insulating layer IL2 and the first insulating layer IL1 respectively.

However, a second source electrode SE2 and a second drain electrode DE2 of the second transistor TR2 are provided on the second semiconductor layer ACT2 to be in contact with the second semiconductor layer ACT2 without any contact hole.

A protective layer PSV is provided on the third insulating layer IL3. The protective layer PSV covers the first transistor TR1 and the second transistor TR2, and may include at least one of an inorganic insulating layer made of an inorganic material and an organic insulating layer made of an organic material.

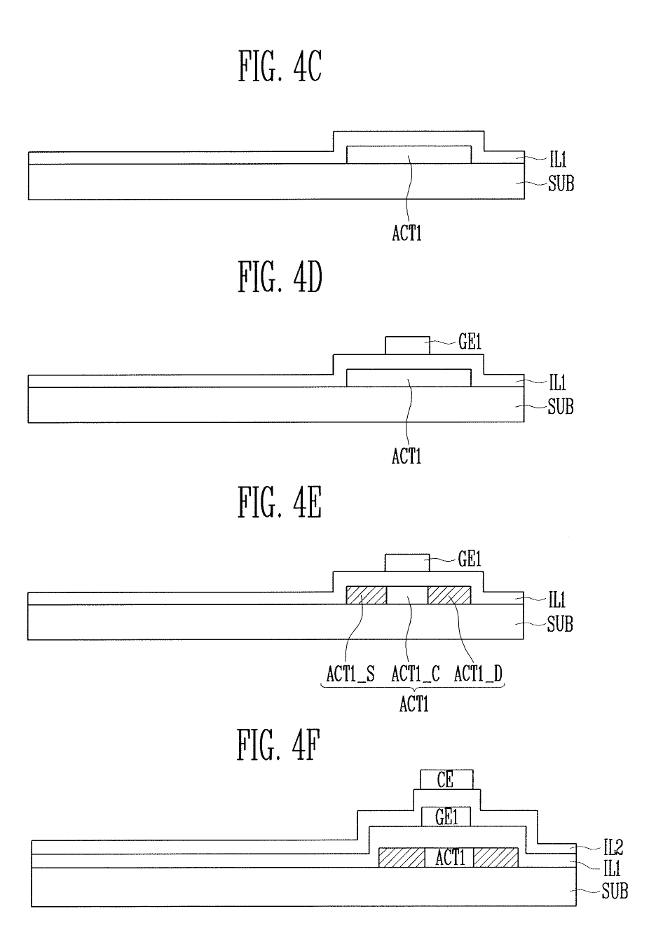

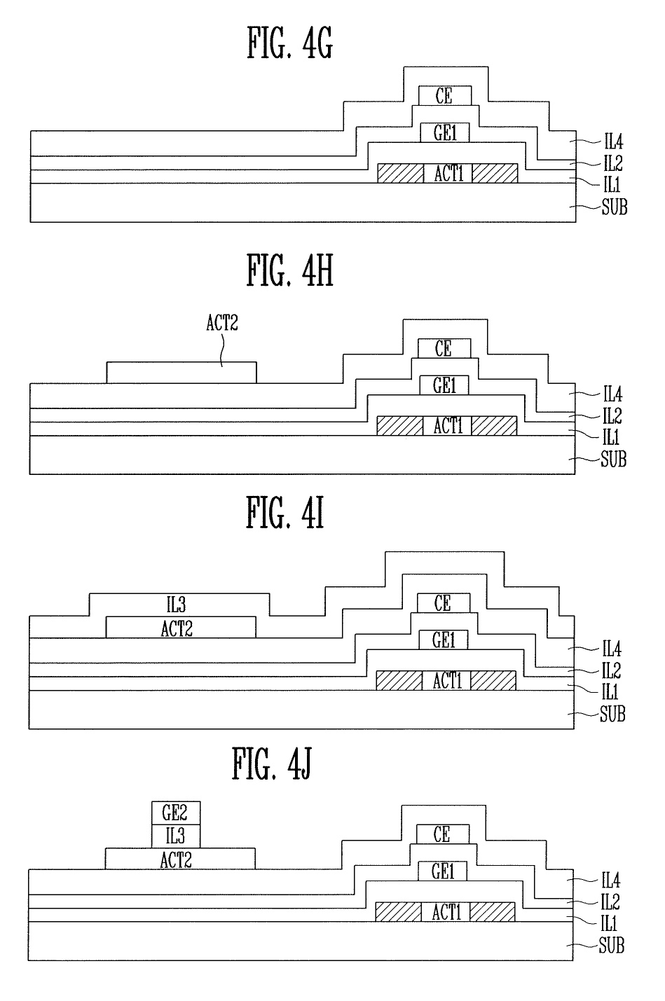

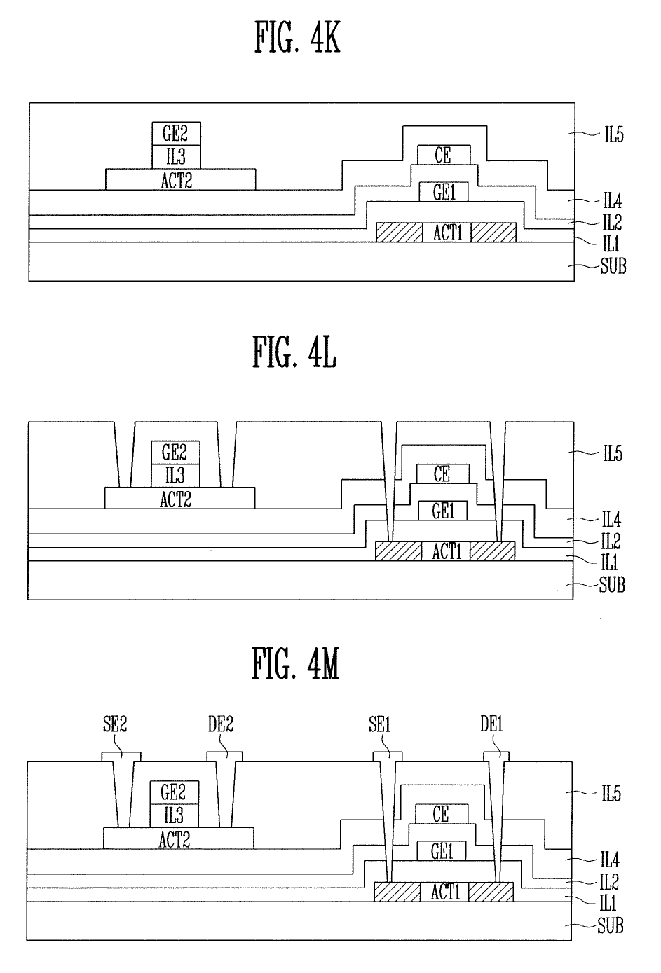

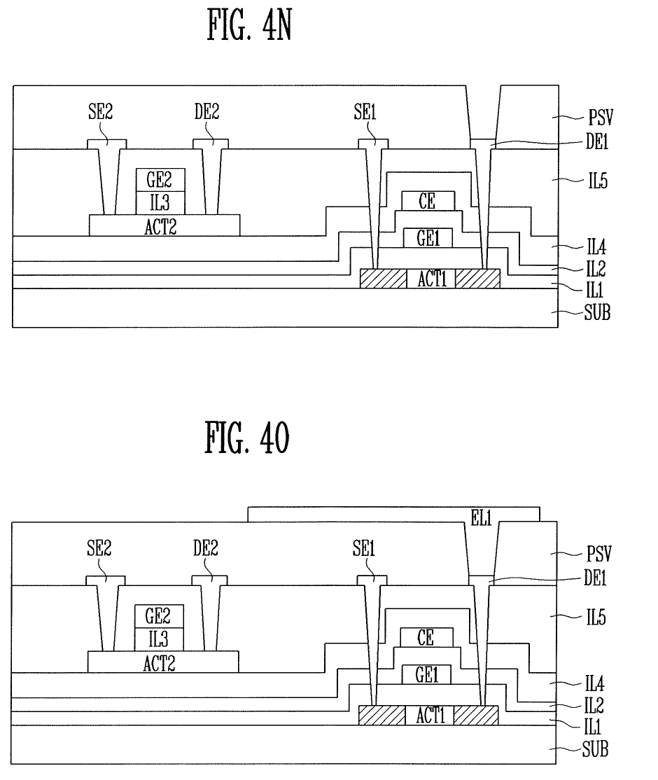

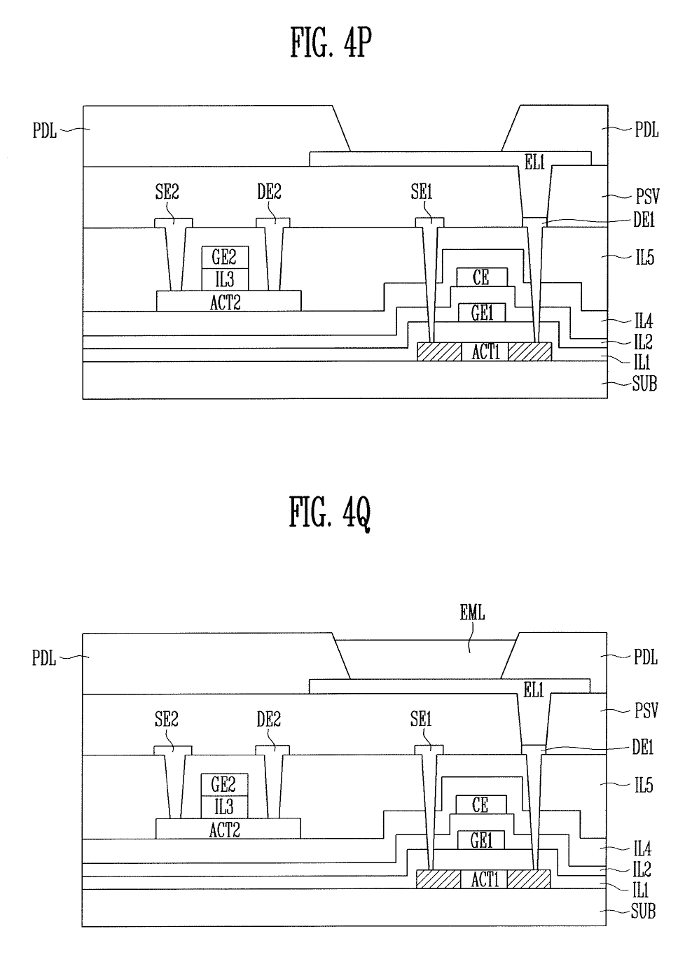

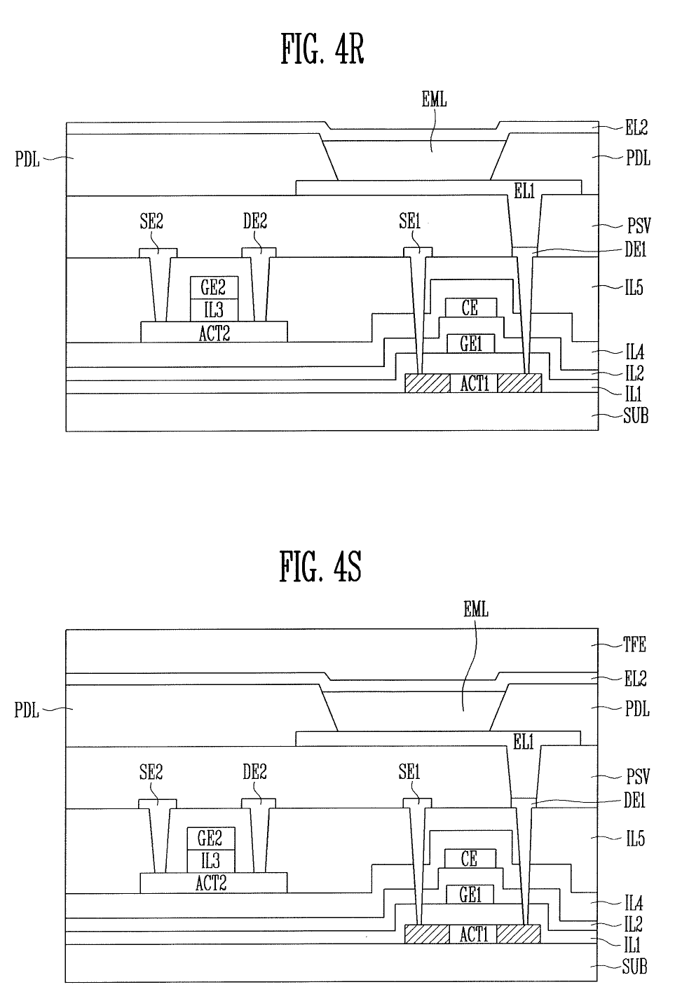

FIGS. 4A to 4S are process sectional views illustrating a manufacturing method of the display device shown in FIG. 1.

First, referring to FIG. 4A, a substrate SUB is provided in the manufacturing of the display device according to the present example embodiment. The substrate SUB may be provided in a processing apparatus for performing a manufacturing process of the display device, such as a deposition chamber.

Referring to FIG. 4B, a first semiconductor layer ACT1 including crystalline silicon is provided on the substrate SUB. As described above, the first semiconductor layer ACT1 may be formed by crystallizing amorphous silicon. In order to crystallize amorphous silicon, there may be used a solid phase crystallization (SPC) method, a metal induced crystallization (MIC) method, a metal induced lateral crystallization (MILC) method, an excimer laser crystallization (ELC) method, or the like.

The first semiconductor layer ACT1 may be formed by entirely stacking amorphous silicon on the substrate SUB, crystallizing the amorphous silicon, and then patterning the amorphous silicon. However, in some cases, the amorphous silicon is first patterned and then crystallized.

The amorphous silicon may be stacked on the substrate SUB, using a sputtering method, a plasma enhanced chemical vapor deposition (PECVD) method, a pulsed laser deposition (PLD) method, an atomic layer deposition (ALD) method, a metal organic chemical vapor deposition (MOCVD) method, a solution process of forming a thin film by spin-coating a soluble precursor and then heat treatment on the soluble precursor, a mist CVD method of forming a thin film by spraying a soluble precursor in a mist form, or the like.

The patterning of the crystalline silicon may be performed using a photolithography method. For example, the first semiconductor layer ACT1 may be formed by forming, on the crystalline silicon, a photoresist mask that includes a photoresist including a photosensitive material, etching the crystalline silicon, using the photoresist mask, and then removing the photoresist mask.

Referring to FIG. 4C, a first insulating layer IL1 is provided over the first semiconductor layer ACT1. The first insulating layer IL1 may include an organic insulating material or an inorganic insulating material as described above. For example, when the first insulating layer IL1 includes an inorganic insulating material, the first insulating layer IL1 may be provided using a sputtering method or a plasma enhanced chemical vapor deposition (PECVD) method. On the other hand, when the first insulating layer IL1 includes an organic insulating material, the first insulating layer IL1 may be provided using a method such as printing or coating.

Referring to FIG. 4D, a first gate electrode GE1 is provided on the first insulating layer IL1. The first gate electrode GE1 includes a conductive material. The first gate electrode GE1 may be formed by entirely stacking a conductive material on the first insulating layer IL1 and then patterning the conductive material. The first gate electrode GE1 may be patterned using a photolithography method. In order to form the first gate electrode GE1, the conductive material may be stacked on the first insulating layer IL1, using a sputtering method, a plasma enhanced chemical vapor deposition (PECVD) method, or the like.

Referring to FIG. 4E, the first semiconductor layer ACT1 may be doped after the first gate electrode GE1 is provided. For example, a source region ACT1_S and a drain region ACT1_D of the first semiconductor layer ACT1 may be doped. In this case, the first gate electrode GE1 may serve as a barrier for doping the first semiconductor layer ACT1. If the first semiconductor layer ACT1 is doped after the first gate electrode GE1 is formed, a region ACT1_C overlapping with the first gate electrode GE1 is not doped. Accordingly, the region that overlaps with the first gate electrode GE1 and is not doped can serve as a channel region ACT1_C of the first semiconductor layer ACT1.

Referring to FIG. 4F, a second insulating layer IL2 is provided on the first gate electrode GE1. Like the first insulating layer IL 1, the second insulating layer IL2 may include at least one selected from an organic insulating material and an inorganic insulating material. An appropriate method of forming the second insulating layer IL2 may be used depending on the kind of the second insulating layer IL2.

Then a capacitor electrode CE is provided on the second insulating layer IL2. Like the first gate electrode GE1, the capacitor electrode CE may be provided by stacking a conductive layer on the second insulating layer IL2 and then patterning the conductive layer.

Referring to FIG. 4G, a fourth insulating layer IL4 is provided over the capacitor electrode CE. Like the first insulating layer IL1, the fourth insulating layer IL4 may include at least one selected from an organic insulating material and an inorganic insulating material. An appropriate method of forming the fourth insulating layer IL4 may be used depending on the kind of the fourth insulating layer IL4.

Referring to FIG. 4H, a second semiconductor layer ACT2 is provided on the fourth insulating layer IL4. The second semiconductor layer ACT2 is provided to be spaced apart from the first semiconductor layer ACT1, and the first semiconductor layer ACT1 and the second semiconductor layer ACT2 do not overlap with each other on a plane. The second semiconductor layer ACT2 includes an oxide semiconductor. The oxide semiconductor may be provided on the fourth insulating layer IL4, using a sputtering method, a plasma enhanced chemical vapor deposition (PECVD) method, a pulsed laser deposition (PLD) method, an atomic layer deposition (ALD) method, a metal organic chemical vapor deposition (MOCVD) method, a solution process of forming a thin film by spin-coating a soluble precursor and then heat treatment on the soluble precursor, a mist CVD method of forming a thin film by spraying a soluble precursor in a mist form, or the like.

Referring to FIG. 41, a third insulating layer IL3 is provided over the second semiconductor layer ACT2. Like the first insulating layer IL1, the third insulating layer IL3 may include at least one selected from an organic insulating material and an inorganic insulating material. An appropriate method of forming the third insulating layer IL3 may be used depending on the kind of the third insulating layer IL3.

Referring FIG. 4J, a second gate electrode GE2 is provided on the third insulating layer IL3. The second gate electrode GE2 includes a first layer, a second layer, and a third layer, which are sequentially stacked, as described above. Since the first layer and the third layer include molybdenum and the second layer includes titanium, the first to third layers may be provided using a sputtering method, a plasma enhanced chemical vapor deposition (PECVD) method, or the like.

The first to third layers are sequentially provided on the third insulating layer IL3. Accordingly, the first to third layers are provided using the same method. For example, all of the first to third layers may be provided using the PECVD method. In this case, a material to be deposited is changed from molybdenum to titanium and from titanium to molybdenum in the same deposition chamber, so that the first to third layers may be sequentially formed. As the first to third layers are provided using one processing apparatus, processing cost may be reduced, and processing efficiency may be improved.

In order to form the first to third layers, a conductive material may be entirely provided on the third insulating layer IL3 and then be patterned. For example, the second gate electrode GE2 including the first to third layers may be patterned through a first etching process of etching the third layer and the second layer and a second etching process of etching the first layer. The patterning of the first to third layers will be described in detail below.

The third insulating layer IL3 may be patterned through a separate etching process or the second etching process of etching the first layer. Therefore, the third insulating layer IL3 may be provided in an island shape having an area similar to that of the second gate electrode GE2. In this embodiment, a case where the third insulating layer IL3 is patterned together with the second gate electrode GE is described as an example, but the present disclosure is not limited thereto. For example, the third insulating layer IL3 may not be patterned together with the second gate electrode GE2.

Referring to FIG. 4K, a fifth insulating layer IL5 may be provided to cover the second gate electrode GE2. The fifth insulating layer IL5 may have a thickness that is thick enough to planarize the surface of the substrate SUB, on which the second gate electrode GE2 is formed.

Referring to FIG. 4L, contact holes are formed after forming the fifth insulating layer IL5. The contact holes may allow source and drain regions of the first semiconductor layer ACT1 and the second semiconductor layer ACT2 to be exposed therethrough, respectively.

Referring to FIG. 4M, first and second source electrodes SE1 and SE2 and first and second drain electrodes DE1 and DE2 are provided on the fifth insulating layer IL5. The first and second source electrodes SE1 and SE2 and the first and second drain electrodes DE1 and DE2 may be in contact with the source and drain regions of the first semiconductor layer ACT1 and the second semiconductor layer ACT2 through the contact holes, respectively.

The first and second source electrodes SE1 and SE2 and the first and second drain electrodes DE1 and DE2 may be formed by forming a conductive material layer on the fifth insulating layer IL5 and patterning the conductive material layer.

Referring to FIG. 4N, a protective layer PSV is provided to cover the first and second source electrodes SE1 and SE2 and the first and second drain electrodes DE1 and DE2. The protective layer PSV may include an opening that allows a portion of the first drain electrode DE1 to be exposed therethrough.

Referring to FIG. 40, a first electrode EL1 is provided on the protective layer PSV. The first electrode EL1 may be in contact with the first drain electrode DE1 through the opening. The first electrode EL1 includes a conductive material. The first electrode EL1 may be formed by entirely coating a conductive material on the protective layer PSV and then patterning the conductive material.

Referring to FIG. 4P, a pixel defining layer PDL is provided over the first electrode EL1. The pixel defining layer PDL may be provided in a shape that allows at least a portion of the first electrode EL1 to be exposed therethrough.

Referring to FIG. 4Q, an emitting layer EML may be provided on the exposed portion of the first electrode ELL The emitting layer EML may be provided on the first electrode EL1, using a method such as deposition. When the emitting layer EML includes various functional layers including a hole injection layer, an electron injection layer, or the like, a plurality of functional layers may be sequentially deposited on the first electrode EL1.

Referring to FIG. 4R, a second electrode EL2 is formed on the pixel defining layer PDL and the emitting layer EML. The second electrode EL2 may be entirely formed or be patterned to overlap with the emitting layer EML.

Referring to FIG. 4S, an encapsulation layer TFE may be provided on the second electrode EL2. The encapsulation layer TFE may include an inorganic layer and/or an organic layer. Therefore, an appropriate method of forming the encapsulation layer TFE may be used depending on the kind of the encapsulation layer TFE. For example, when the encapsulation layer TFE has a form in which inorganic and organic layers are alternately stacked in an order of inorganic layer/organic layer/inorganic layer, the process of forming the encapsulation layer IFE may be performed in an order of deposition of the inorganic layer, printing or coating of the organic layer, and deposition of the inorganic layer.

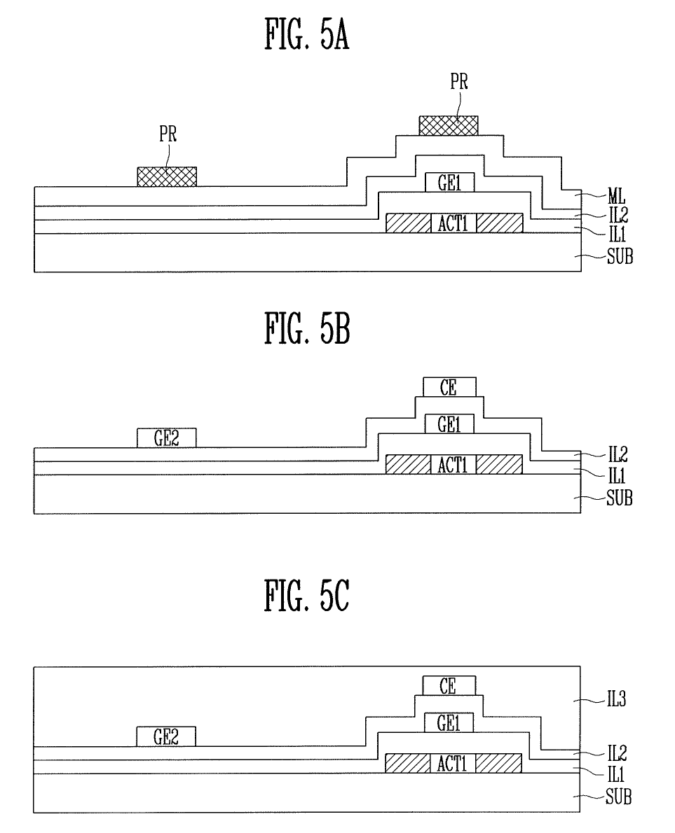

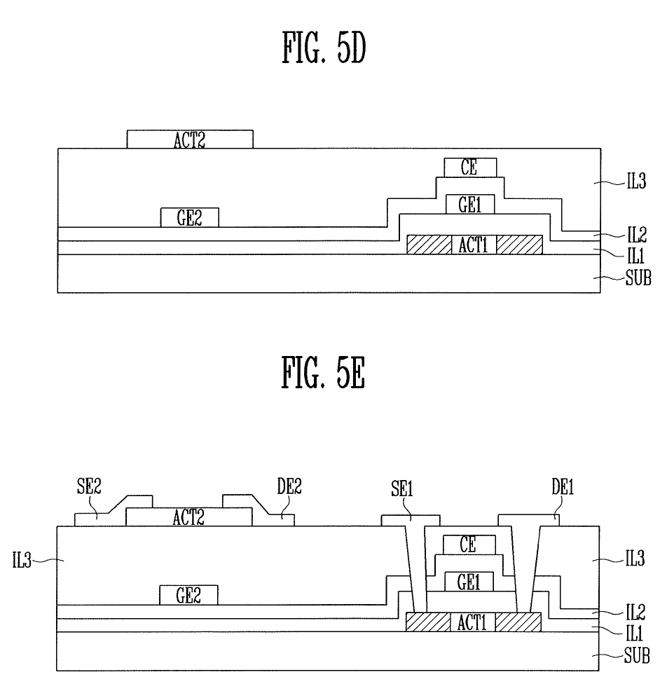

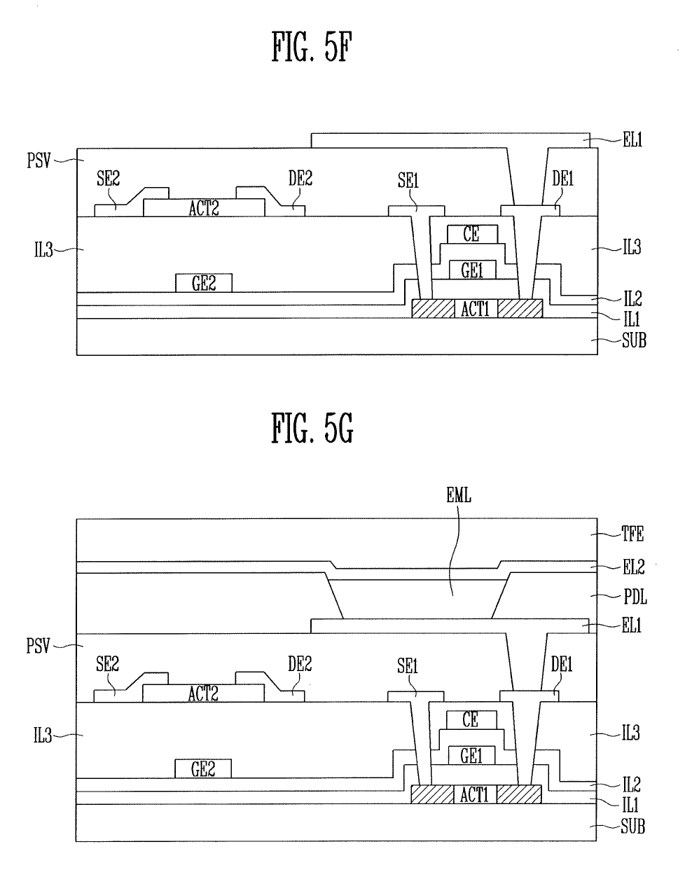

FIGS. 5A to 5G are process sectional views illustrating a manufacturing method of the display device shown in FIG. 3.

First, processes performed until a second insulating layer IL2 is formed are the same as the above-described processes.

Referring to FIGS. 5A and 5B, a conductive layer ML is entirely provided on the second insulating layer IL2. A capacitor electrode CE and a second gate electrode GE2 may be formed by patterning the conductive layer ML.

The conductive layer ML may be formed by forming a lower layer including molybdenum on the second insulating layer IL2, forming a middle layer including titanium on the lower layer, and forming an upper layer including molybdenum on the middle layer. The lower layer, the middle layer, and the upper layer may be formed in the same chamber, using the same method, e.g., a deposition method or a sputtering method.

The patterning of the conductive layer ML may be performed using a photolithography method. Therefore, a photoresist PR is provided in regions in which the capacitor electrode CE and the second gate electrode GE2 are to be formed on the conductive layer ML. The state shown in FIG. 5A illustrates a state after a photoresist including a photosensitive material is coated and then developed.

According to this embodiment, the capacitor electrode CE and the second gate electrode GE2 are provided in the same layer through the same process. Accordingly. the capacitor electrode CE and the second gate electrode GE2 include the same material. According to the present example embodiment, like the second gate electrode GE2. the capacitor electrode CE may include a first layer including molybdenum, a second layer including titanium, and a third layer including molybdenum, which are sequentially stacked.

The second gate electrode GE2 and the capacitor electrode CE, each of which includes the first to third layers, may be patterned through a first etching process of etching the third layer and the second layer and a second etching process of etching the first layer. The patterning of the first to third layers will be described in detail below.

Referring to FIG. 5C, a third insulating layer IL3 is formed over the second gate electrode GE2 and the capacitor electrode CE.

Referring to FIG. 5D, a second semiconductor layer ACT2 is provided on the third insulating layer IL3. The second semiconductor layer ACT2 may be provided on the third insulating layer IL3, using a sputtering method, a plasma enhanced chemical vapor deposition (PECVD) method, a pulsed laser deposition (PLD) method, an atomic layer deposition (ALD) method, a metal organic chemical vapor deposition (MOCVD) method, a solution process of forming a thin film by spin-coating a soluble precursor and then heat treatment on the soluble precursor, a mist CVD method of forming a thin film by spraying a soluble precursor in a mist form, or the like.

Referring to FIG. 5E, first and second source electrodes SE1 and SE2 and first and second drain electrodes DE1 and DE2 are provided. A process of forming contact holes that allow the first source and drain electrodes SE1 and DE1 of the first semiconductor layer ACT1 to be exposed therethrough by passing through the third insulating layer IL3, the second insulating layer IL2, and the first insulating layer IL1 may be precede before the first source electrode SE1 and the first drain electrode DE1 are provided. The second source electrode SE2 and the second drain electrode DE2 may be provided immediately on the second semiconductor layer ACT2 without any contact hole.

Referring to FIG. 5F, a protective layer PSV is provided over the first and second source electrodes SE1 and SE2 and the first and second drain electrodes DE1 and DE2. The protective layer PSV is provided to cover first and second transistors TR1 and TR2. In addition, the protective layer PSV may allow a portion of the first drain electrode DE1 to be exposed therethrough.

A first electrode EL1 is provided on the protective layer PSV. The first electrode EL1 may be connected to the first drain electrode DEL

Referring to FIG. 5G, a pixel defining layer PDL that allows the first electrode EL1 to be exposed therethrough, an emitting layer EML on the first electrode EL1, a second electrode EL2 on the emitting layer EML, and an encapsulation layer TFE on the second electrode EL2 are provided on the first electrode EL1.

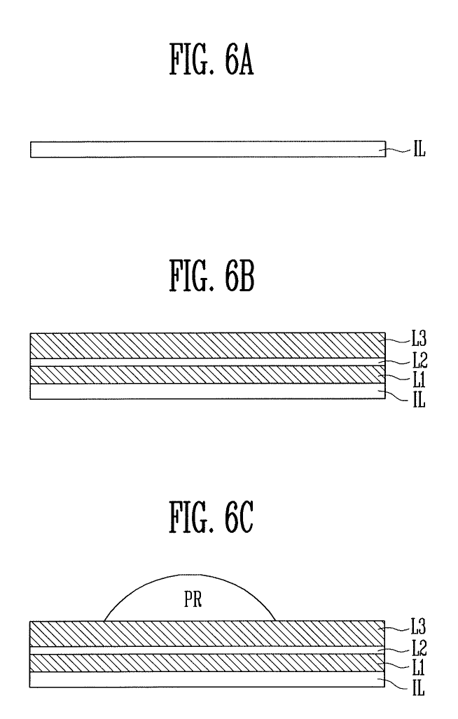

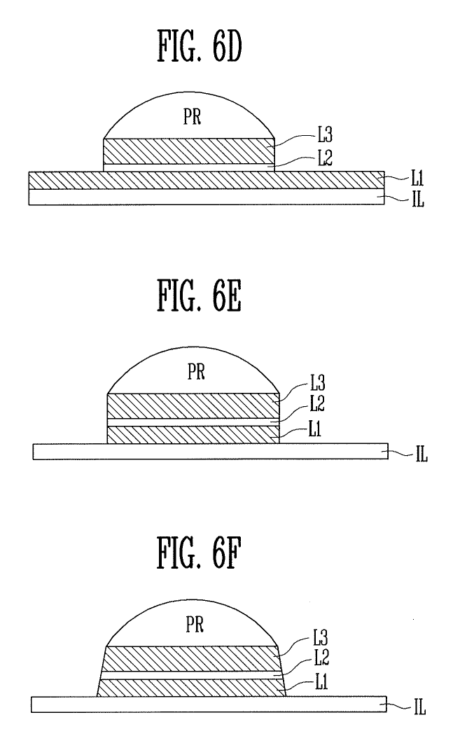

FIGS. 6A to 6F are process sectional views illustrating an electrode forming method according to an embodiment.

Referring to FIGS. 6A and 6B, a first layer L1, a second layer L2, and a third layer L3 are sequentially stacked on an insulating layer IL. In order to provide the first layer L1, the second layer L2, and the third layer L3 on the insulating layer IL, the first to third layers L1 to L3 may be provided using different methods for every layer. For example, the first layer L1 may be formed using a sputtering method, and the second layer L2 and the third layer L3 may be formed using a plasma enhanced chemical vapor deposition (PECVD) method. However, when the layers are formed using different methods, several processing chambers are required. Therefore, processing efficiency may be decreased, and processing cost may be increased. Accordingly, the first to third layers L1 to L3 may be formed in the same chamber, using the same method. For example, the first to third layers L1 to L3 may be formed in one deposition chamber, using a plasma enhanced chemical vapor deposition (PECVD) method.

The first to third layers L1 to L3 may have thicknesses different from one another. For example, the thickness of the third layer L3 may be thickest. The thickness of each layer may be adjusted through a process time. For example, the second layer L2 may be formed thicker than the other layers by increasing a deposition process time to be relatively long.

Referring to FIG. 6C, a photoresist PR is provided on the third layer L3. The photoresist PR may remain in a partial region by being entirely coated on the third layer L3 and then being subjected to exposure and development processes.

Referring to FIG. 6D, a first etching process is performed after the photoresist PR is provided. The third layer L3 and the second layer L2, which located in a region in which the photoresist PR is not provided, are removed in the first etching process. However, a portion of the first layer L1 may be removed together with the third layer L3 and the second layer L2 in the first etching process.

The first etching process may be performed using a dry etching method. A fluid for etching in a gas state may be used in a dry etching process. The dry etching process may be performed in a vacuum chamber. For example, the state of the fluid for etching may be transformed to a plasma state by providing the first to third layers L1 to L3 and the fluid for etching to the vacuum chamber and applying a voltage to the fluid for etching.

The fluid for etching in the plasma state may create a reaction product in a gas state by reacting with the second layer L2 and the third layer L3. The reaction product is obtained as ions or radicals included in the fluid for etching react with metal atoms, and the state of the reaction product is a gas state. Hence, the reaction product is easily removed from the insulating layer IL.

In the first etching process, the fluid for etching may include sulfur hexafluoride (SF₆) and oxygen (O₂). As a voltage is applied to the sulfur hexafluoride (SF₆) in the vacuum chamber, the state of the sulfur hexafluoride (SF₆) may be transformed to a plasma state as follows.

SF₆→SF₅+e⁻+F radical Chemical Formula 1

The F radical may create titanium fluoride or molybdenum fluoride by reacting with titanium or molybdenum. Since the titanium fluoride or molybdenum fluoride is in a gas state, the titanium fluoride or molybdenum fluoride is easily removed on the insulating layer IL.

The oxygen injected into the vacuum chamber along with the sulfur hexafluoride (SF₆) may serve as a catalyst for helping plasma transformation of the sulfur hexafluoride (SF₆).

The etching speed of the fluid for etching, which is used in the first etching process, with respect to the third layer L3 may be about 0.9 times to about 1.1 times of that of the fluid for etching, which is used in the first etching process, with respect to the second layer L2. Thus, the fluid for etching, which is used in the first etching process, etches the third layer L3 and the second layer L2 at similar speeds, and accordingly, the etched surfaces of the third layer L3 and the second layer L2 may be smoothly continued without any step difference. When the etching speeds of the two layers are different by a degree out of the above-described range, the layer etched at a fast etching speed may be further etched than the layer etched at a slow etching speed. Therefore, a step difference may occur between the etched surfaces of the two layers.

Referring to FIG. 6E and 6F, a second etching process may also be performed using a dry etching method. The first layer L1 is removed in the second etching process. In the second etching process, a fluid for etching may include chlorine (Cl₂) and oxygen (O₂). As a voltage is applied to the chlorine (Cl₂) in the vacuum chamber, the state of the chlorine (Cl₂) may be transformed to a plasma state.

The chlorine (Cl₂) in the plasma state may create molybdenum chloride by reacting with molybdenum of the first layer L1. Since the molybdenum chloride is in a gas state, the molybdenum chloride is easily removed on the insulating layer IL.

Since the third layer L3 and the second layer L2 are removed together in the first etching process, the processing time of the first etching process may be longer than that of the second etching process of removing only the first layer L1.

According to the present example embodiment, a multi-layered electrode may be patterned through using two etching processes. Accordingly, processes may be simplified and processing efficiency may be improved.

The etched surfaces of the first to third layers L1 and L3 may be smoothly continued without any step difference. In particular, as shown in FIG. 6F, the etched surfaces of the first to third layers L1 to L3 may have a tapered shape at ends thereof. In this case, the etched surfaces of the first to third layers L1 to L3 have the substantially same inclination, and accordingly, the end of an electrode can have an inclined shape having one inclination.

The electrode including the first to third layers L1 to L3 may be applied to the second gate electrode GE2 shown in drawings. In addition, the first to third layer L1 to L3 may also be applied to the first gate electrode GE1 or the capacitor electrode CE, which is shown in drawings. In addition, the first to third layer L1 to L3 may be applied to another electrode or line, which is not shown in FIGS. 1 to 5G.

As described above, embodiments may prevent an electrode from being oxidized at an interface between the electrode and an insulating layer.

In addition, embodiments may simplify a manufacturing method of the display device, thereby improving process efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed

1

s:

1. A display device comprising:
a substrate;
first and second transistors provided on the substrate to be spaced apart from each other; and
a display unit electrically connected to the first transistor,
wherein the first transistor includes a first semiconductor layer including crystalline silicon, a first gate electrode, a first source electrode, and a first drain electrode, wherein the second transistor includes a second semiconductor layer including an oxide semiconductor, a second gate electrode, a second source electrode, and a second drain electrode, and
wherein the second gate electrode includes a first layer that is provided on an insulating layer and includes molybdenum, a second layer that is provided on the first layer and includes titanium, and a third layer that is provided on the second layer and includes molybdenum.

2. The display device as claimed in claim 1, further comprising:
a first insulating layer provided between the first gate electrode and the first semiconductor layer;
a second insulating layer provided over the first gate electrode; and
a third insulating layer provided between the second gate electrode and the second semiconductor layer,
wherein the insulating layer is one of the second insulating layer and the third insulating layer.

3. The display device as claimed in claim 2, wherein the second gate electrode is provided on the third insulating layer.

4. The display device as claimed in claim 3, further comprising:
a capacitor electrode provided on the second insulating layer; and
a fourth insulating layer covering the capacitor electrode, the fourth insulating layer being provided between the second insulating layer and the second semiconductor layer.

5. The display device as claimed in claim 4, wherein at least one selected from the first gate electrode and the capacitor electrode includes the first layer, the second layer on the first layer, and the third layer on the second layer.

6. The display device as claimed in claim 2, wherein the second gate electrode is provided on the second insulating layer, and the second semiconductor layer is provided on the third insulating layer.

7. The display device as claimed in claim 6, further comprising a capacitor electrode provided on the second insulating layer, the capacitor electrode overlapping with the first gate electrode.

8. The display device as claimed in claim 7, wherein at least one selected from the first gate electrode and the capacitor electrode includes the first layer, the second layer on the first layer, and the third layer on the second layer.

9. The display device as claimed in claim 1, wherein the thickness of the third layer is thicker than that of the first layer.

10. The display device as claimed in claim 1, wherein the display unit includes:
a first electrode electrically connected to the first drain electrode;
a second electrode provided on the first electrode; and
an emitting layer provided between the first electrode and the second electrode.

11. A method of manufacturing a display device, the method comprising:
providing a first semiconductor layer including crystalline silicon on a substrate;
providing a first insulating layer over the first semiconductor layer;
providing a first gate electrode on the first insulating layer;
providing a second insulating layer over the first gate electrode;
providing, on the second insulating layer, a second semiconductor layer spaced apart from the first gate electrode, the second semiconductor layer including an oxide semiconductor;
providing a third insulating layer over the second semiconductor layer; and
providing a second gate electrode on the third insulating layer,
wherein the second gate electrode includes a first layer that is provided on the third insulating layer and includes molybdenum, a second layer that is provided on the first layer and includes titanium, and a third layer that is provided on the second layer and includes molybdenum,
wherein the providing of the second gate electrode includes:
a first etching process of etching the second layer and the third layer; and
a second etching process of etching the first layer.

12. The method as claimed in claim 11, further comprising: between the providing of the second insulating layer and the providing of the second semiconductor layer,
forming a capacitor electrode overlapping the first gate electrode on the second insulating layer; and
providing a fourth insulating layer provided over the capacitor electrode.

13. The method as claimed in claim 11, wherein the etching speed of an etching gas used in the first etching process with respect to the third layer is 0.9 times to 1.1 times of that of the etching gas used in the first etching process with respect to the second layer.

14. The method as claimed in claim 13, wherein the etching gas used in the first etching process includes sulfur hexafluoride (SF₆) and oxygen (O₂), and
an etching gas used in the second etching process includes chlorine (Cl₂) and oxygen (O₂).

15. A method of manufacturing a display device, the method comprising:
providing a first semiconductor layer including crystalline silicon on a substrate;
providing a first insulating layer over the first semiconductor layer;
providing a first gate electrode on the first insulating layer;
providing a second insulating layer over the first gate electrode;
providing a second gate electrode spaced apart from the first gate electrode on the second insulating layer;
providing a third insulating layer over the second gate electrode; and
providing a second semiconductor layer including an oxide semiconductor on the third insulating layer,
wherein the second gate electrode includes a first layer that is provided on the third insulating layer and includes molybdenum, a second layer that is provided on the first layer and includes titanium, and a third layer that is provided on the second layer and includes molybdenum,
wherein the providing of the second gate electrode includes:
a first etching process of etching the second layer and the third layer; and
a second etching process of etching the first layer.

16. The method as claimed in claim 15, further comprising providing a capacitor electrode that is provided on the second insulating layer, overlaps with the first gate electrode, and is simultaneously formed with the second gate electrode.

17. The method as claimed in claim 15, wherein the etching speed of an etching gas used in the first etching process with respect to the third layer is 0.9 times to 1.1 times of that of the etching gas used in the first etching process with respect to the second layer.

18. The method as claimed in claim 17, wherein the etching gas used in the first etching process includes sulfur hexafluoride (SF₆) and oxygen (O₂), and an etching gas used in the second etching process includes chlorine (Cl₂) and oxygen (O₂).

19. A method of forming an electrode, the method comprising:
sequentially forming a first layer that includes molybdenum, a second layer that is provided on the first layer and includes titanium, and a third layer that is provided on the second layer and includes molybdenum;
a first etching process of etching the third layer and the second layer in a lump; and
a second etching process of etching the first layer,
wherein the etching speed of an etching gas used in the first etching process with respect to the third layer is 0.9 times to 1.1 times of that of the etching gas used in the first etching process with respect to the second layer.

20. The method as claimed in claim 19, wherein the etching gas used in the first etching process includes sulfur hexafluoride (SF₆) and oxygen (O₂), and
an etching gas used in the second etching process includes chlorine (Cl₂) and oxygen (O₂).
